(19) United States
(12) Patent Application Publication
(10) Pub. No.: US 2015/0064970 A1
(43) Pub. Date: Mar. 5, 2015

(54) SYSTEMS, APPARATUS, AND METHODS FOR AN EMBEDDED EMISSIONS FILTER CIRCUIT IN A POWER CABLE

(71) Applicant: QUALCOMM Incorporated, San Diego, CA (US)

(72) Inventors: Zhen Ning Low, San Diego, CA (US); Fang Han, San Diego, CA (US)

(73) Assignee: QUALCOMM Incorporated, San Diego, CA (US)

(21) Appl. No.: 14/166,182

(22) Filed: Jan. 28, 2014

Related U.S. Application Data
(60) Provisional application No. 61/873,723, filed on Sep. 4, 2013.

(51) Int. Cl. H01R 13/719; H03H 7/01

(52) U.S. Cl. CPC H01R 13/719; H03H 7/0138
USPC 439/620.01; 333/167

(57) ABSTRACT

Systems, methods and apparatus are disclosed for filtering. In one aspect a power cable apparatus is provided. The apparatus includes a cable portion. The apparatus further includes a first connector portion coupled to a first end of the cable portion. The apparatus further includes a second connector portion coupled to a second end of the cable portion opposite the first end. The apparatus further includes a filter circuit integrated within the second the connector portion, the filter circuit configured to attenuate emissions at an operating frequency of the electronic device.

### CLAIM OF PRIORITY UNDER 35 U.S.C. §119

The present application for patent claims priority to Provisional Application No. 61/873,723 entitled “SYSTEMS, APPARATUS, AND METHODS FOR AN EMBEDDED EMISSIONS FILTER CIRCUIT IN A POWER CABLE” filed Sep. 4, 2013, and assigned to the assignee hereof. Provisional Application No. 61/873,723 is hereby expressly incorporated by reference herein.

### FIELD

The present disclosure relates generally to a filter circuit for controlling emissions where the filter circuit is integrated within a power cable.

### BACKGROUND

An increasing number and variety of electronic devices are portable and may be powered via cables. For example, a wireless power transmitter may be powered via a USB cable connected to a power supply. In some cases a device coupled to a cable may produce emissions in the cable that may be undesirable.

### SUMMARY

Various implementations of systems, methods and devices within the scope of the appended claims each have several aspects, no single one of which is solely responsible for the desirable attributes described herein. Without limiting the scope of the appended claims, some prominent features are described herein.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

One aspect of the subject matter described in the disclosure provides a power cable apparatus. The apparatus includes a cable portion. The apparatus further includes a first connector portion coupled to a first end of the cable portion and configured to selectively couple to an electronic device. The apparatus further includes a second connector portion coupled to a second end of the cable portion opposite the first end. The apparatus further includes a filter circuit integrated within the second connector portion. The filter circuit is configured to attenuate emissions at an operating frequency of the electronic device.

Another aspect of the subject matter described in the disclosure provides an implementation of a method of filtering within a power cable apparatus. The method includes providing power to an electronic device via a first connector portion coupled to a first end of a cable portion of the power cable apparatus. The method further includes filtering emissions at an operating frequency of the electronic device via a filter circuit integrated within a second connector portion coupled to a second end of the cable portion opposite the first end of the cable portion of the power cable apparatus.

Yet another aspect of the subject matter described in the disclosure provides a DC power cable apparatus. The apparatus includes means for connecting to an electronic device for providing power. The apparatus includes means for connecting to a power supply. The apparatus includes means for attenuating emissions an operating frequency of the electronic device, the means for attenuating being integrated within the means for connecting to the power supply.

### BRIEF DESCRIPTION OF THE DRAWINGS

FIG. 1 is a functional block diagram of an exemplary wireless power transfer system, in accordance with exemplary embodiments of the invention.

FIG. 2 is a functional block diagram of exemplary components that may be used in the wireless power transfer system of FIG. 1, in accordance with various exemplary embodiments of the invention.

FIG. 3 is a schematic diagram of a portion of transmit circuitry or receive circuitry of FIG. 2 including a transmit or receive antenna, in accordance with exemplary embodiments of the invention.

FIG. 4 is a functional block diagram of a transmitter that may be used in the wireless power transfer system of FIG. 1, in accordance with exemplary embodiments of the invention.

FIG. 5 is a functional block diagram of a receiver that may be used in the wireless power transfer system of FIG. 1, in accordance with exemplary embodiments of the invention.

FIG. 6 is a schematic diagram of a portion of transmit circuitry that may be used in the transmit circuitry of FIG. 4, in accordance with exemplary embodiments.

FIG. 7A is a diagram of a power cable apparatus, in accordance with an exemplary embodiment.

FIG. 7B is diagram of a portion of the cable of FIG. 7A, in accordance with an embodiment.

FIG. 8 is a schematic diagram of a filter circuit that may be integrated within the cable of FIGS. 7A and 7B, in accordance with an embodiment.

FIG. 9 is a flow chart of an exemplary method of filtering within a power cable apparatus, in accordance with an exemplary embodiment.

FIG. 10 is a functional block diagram of a power cable apparatus, in accordance with an exemplary embodiment.

The various features illustrated in the drawings may not be drawn to scale. Accordingly, the dimensions of the various features may be arbitrarily expanded or reduced for clarity. In addition, some of the drawings may not depict all of the components of a given system, method or device. Finally, like reference numerals may be used to denote like features throughout the specification and figures.

### DETAILED DESCRIPTION

The detailed description set forth below in connection with the appended drawings is intended as a description of exemplary embodiments of the invention and is not intended to represent the only embodiments in which the invention may be practiced. The term “exemplary” used throughout this description means “serving as an example, instance, or illustration,” and should not necessarily be construed as preferred or advantageous over other exemplary embodiments. The detailed description includes specific details for the purpose of providing a thorough understanding of the exemplary embodiments of the invention. In some instances, some devices are shown in block diagram form.

Wirelessly transferring power may refer to transferring any form of energy associated with electric fields, magnetic fields, electromagnetic fields, or otherwise from a transmitter to a receiver without the use of physical electrical conductors (e.g., power may be transferred through free space). The power output into a wireless field (e.g., a magnetic field) may be received, captured by, or coupled by a “receiving antenna” to achieve power transfer.

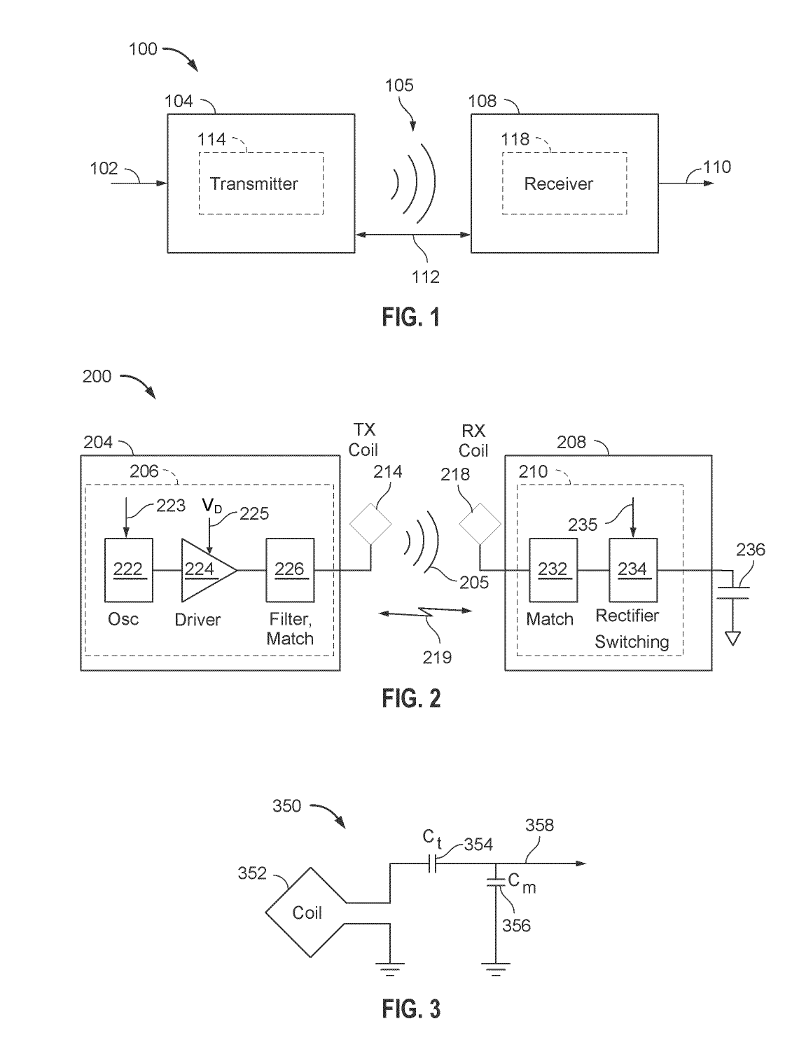

FIG. 1 is a functional block diagram of an exemplary wireless power transfer system 100, in accordance with exemplary embodiments of the invention. Input power 102 may be provided to a transmitter 104 from a power source (not shown) for generating a field 105 for providing energy transfer. A receiver 108 may couple to the field 105 and generate output power 110 for storing or consumption by a device (not shown) coupled to the output power 110. Both the transmitter 104 and the receiver 108 are separated by a distance 112. In one exemplary embodiment, transmitter 104 and receiver 108 are configured according to a mutual resonant relationship. When the resonant frequency of receiver 108 and the resonant frequency of transmitter 104 are substantially the same or very close, transmission losses between the transmitter 104 and the receiver 108 are minimal. As such, wireless power transfer may be provided over larger distance in contrast to purely inductive solutions that may require large coils that require coils to be very close (e.g., mms). Resonant inductive coupling techniques may thus allow for improved efficiency and power transfer over various distances and with a variety of inductive coil configurations.

The receiver 108 may receive power when the receiver 108 is located in an energy field 105 produced by the transmitter 104. The field 105 corresponds to a region where energy output by the transmitter 104 may be captured by a receiver 105. In some cases, the field 105 may correspond to the “near-field” of the transmitter 104 as will be further described below. The transmitter 104 may include a transmit antenna 114 for outputting an energy transmission. The receiver 108 further includes a receive antenna 118 for receiving or capturing energy from the energy transmission. The near-field may correspond to a region in which there are strong reactive fields resulting from the currents and charges in the transmit antenna 114 that minimally radiate power away from the transmit antenna 114. In some cases the near-field may correspond to a region that is within about one wavelength (or a fraction thereof) of the transmit antenna 114. The transmit and receive antennas 114 and 118 are sized according to applications and devices to be associated therewith. As described above, efficient energy transfer may occur by coupling a large portion of the energy in a field 105 of the transmit antenna 114 to a receive antenna 118 rather than propagating most of the energy in an electromagnetic wave to the far field. When positioned within the field 105, a “coupling mode” may be developed between the transmit antenna 114 and the receive antenna 118. The area around the transmit and receive antennas 114 and 118 where this coupling may occur is referred to herein as a coupling-mode region.

FIG. 2 is a functional block diagram of exemplary components that may be used in the wireless power transfer system 100 of FIG. 1, in accordance with various exemplary embodiments of the invention. The transmitter 204 may include transmit circuitry 206 that may include an oscillator 222, a driver circuit 224, and a filter and matching circuit 226. The oscillator 222 may be configured to generate a signal at a desired frequency, such as 468.75 KHz, 6.78 MHz or 13.56 MHz, that may be adjusted in response to a frequency control signal 223. The oscillator signal may be provided to a driver circuit 224 configured to drive the transmit antenna 214 at, for example, a resonant frequency of the transmit antenna 214. The driver circuit 224 may be a switching amplifier configured to receive a square wave from the oscillator 222 and output a sine wave. For example, the driver circuit 224 may be a class E amplifier. A filter and matching circuit 226 may be also included to filter out harmonics or other unwanted frequencies and match the impedance of the transmitter 204 to the transmit antenna 214. As a result of driving the transmit antenna 214, the transmitter 204 may wirelessly output power at a level sufficient for charging or power an electronic device. As one example, the power provided may be for example on the order of 300 milliWatts to 5 Watts to power or charge different devices with different power requirements. Higher or lower power levels may also be provided.

The receiver 208 may include receive circuitry 210 that may include a matching circuit 232 and a rectifier and switching circuit 234 to generate a DC power output from an AC power input to charge a battery 236 as shown in FIG. 2 or to power a device (not shown) coupled to the receiver 108. The matching circuit 232 may be included to match the impedance of the receive circuitry 210 to the receive antenna 218. The receiver 208 and transmitter 204 may additionally communicate on a separate communication channel 219 (e.g., Bluetooth, zigbee, cellular, etc). The receiver 208 and transmitter 204 may alternatively communicate via in-band signaling using characteristics of the wireless field 206.

As described more fully below, receiver 208, that may initially have a selectively disablable associated load (e.g., battery 236), may be configured to determine whether an amount of power transmitted by transmitter 204 and receiver by receiver 208 is appropriate for charging a battery 236. Further, receiver 208 may be configured to enable a load (e.g., battery 236) upon determining that the amount of power is appropriate. In some embodiments, a receiver 208 may be configured to directly utilize power received from a wireless power transfer field without charging of a battery 236. For example, a communication device, such as a near-field communication (NFC) or radio-frequency identification device (RFID may be configured to receive power from a wireless power transfer field and communicate by interacting with the wireless power transfer field and/or utilize the received power to communicate with a transmitter 204 or other devices.

FIG. 3 is a schematic diagram of a portion of transmit circuitry 206 or receive circuitry 210 of FIG. 2 including a transmit or receive antenna 352, in accordance with exemplary embodiments of the invention. As illustrated in FIG. 3, transmit or receive circuitry 350 used in exemplary embodiments including those described below may include an antenna 352. The antenna 352 may also be referred to or be configured as a “loop” antenna 352. The antenna 352 may also be referred to herein or be configured as a “magnetic” antenna or an induction coil. The term “antenna” generally refers to a component that may wirelessly output or receive energy for coupling to another “antenna.” The antenna may also be referred to as a coil of a type that is configured to wirelessly output or receive power. As used herein, an antenna 352 is an example of a “power transfer component” of a type that is configured to wirelessly output and/or receive power. The antenna 352 may be configured to include an air core or a physical core such as a ferrite core (not shown). Air core loop antennas may be more tolerable to extraneous physical devices placed in the vicinity of the core. Furthermore, an air core loop antenna 352 allows the placement of other components within the core area. In addition, an air core loop may more readily enable placement of the receive antenna 218 (FIG. 2) within a plane of the transmit antenna 214 (FIG. 2) where the coupled-mode region of the transmit antenna 214 (FIG. 2) may be more powerful.

As stated, efficient transfer of energy between the transmitter 104 and receiver 108 may occur during matched or nearly matched resonance between the transmitter 104 and the receiver 108. However, even when resonance between the transmitter 104 and receiver 108 are not matched, energy may be transferred, although the efficiency may be affected. Transfer of energy occurs by coupling energy from the field 105 of the transmit antenna 214 coil to the receive antenna 218 residing in the neighborhood where this field 105 is established rather than propagating the energy from the transmit antenna 214 into free space.

The resonant frequency of the loop or magnetic antennas is based on the inductance and capacitance. Inductance may be simply the inductance created by the antenna 352, whereas, capacitance may be added to the antenna's inductance to create a resonant structure at a desired resonant frequency. As a non-limiting example, capacitor 352 and capacitor 354 may be added to the transmit or receive circuitry 350 to create a resonant circuit that selects a signal 356 at a resonant frequency. Accordingly, for larger diameter antennas, the size of capacitance needed to sustain resonance may decrease as the diameter or inductance of the loop increases. Furthermore, as the diameter of the antenna increases, the efficient energy transfer area of the near-field may increase. Other resonant circuits formed using other components are also possible. As another non-limiting example, a capacitor may be placed in parallel between the two terminals of the antenna 350. For transmit antennas, a signal 358 with a frequency that substantially corresponds to the resonant frequency of the antenna 352 may be an input to the antenna 352.

In one embodiment, the transmitter 104 may be configured to output a time varying magnetic field with a frequency corresponding to the resonant frequency of the transmit antenna 114. When the receiver is within the field 105, the time varying magnetic field may induce a current in the receive antenna 118. As described above, if the receive antenna 118 is configured to be resonant at the frequency of the transmit antenna 118, energy may be efficiently transferred. The AC signal induced in the receive antenna 118 may be rectified as described above to produce a DC signal that may be provided to charge or to power a load.

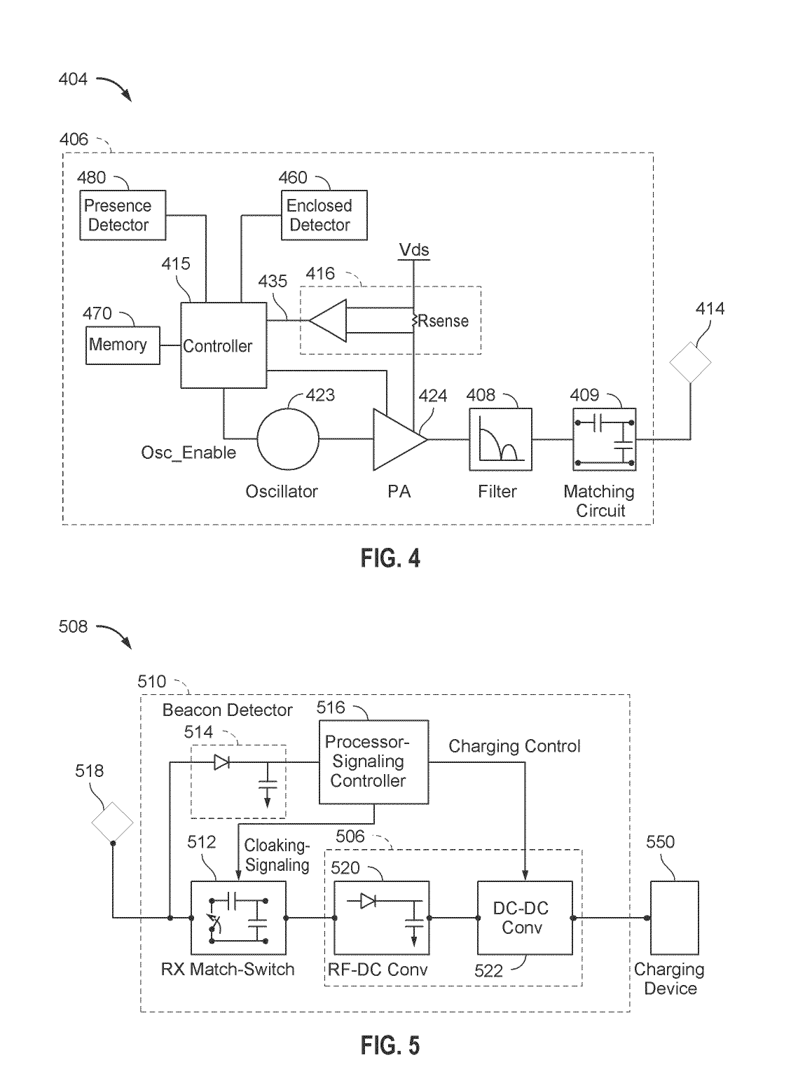

FIG. 4 is a functional block diagram of a transmitter 404 that may be used in the wireless power transfer system of FIG. 1, in accordance with exemplary embodiments of the invention. The transmitter 404 may include transmit circuitry 406 and a transmit antenna 414. The transmit antenna 414 may be the antenna 352 as shown in FIG. 3. Transmit circuitry 406 may provide RF power to the transmit antenna 414 by providing an oscillating signal resulting in generation of energy (e.g., magnetic flux) about the transmit antenna 414. Transmitter 404 may operate at any suitable frequency. By way of example, transmitter 404 may operate at the 6.78 MHz ISM band.

Transmit circuitry 406 may include a fixed impedance matching circuit 409 for matching the impedance of the transmit circuitry 406 (e.g., 50 ohms) to the transmit antenna 414 and a low pass filter (LPF) 408 configured to reduce harmonic emissions to levels to prevent self-jamming of devices coupled to receivers 108 (FIG. 1). Other exemplary embodiments may include different filter topologies, including but not limited to, notch filters that attenuate specific frequencies while passing others and may include an adaptive impedance match, that may be varied based on measurable transmit metrics, such as output power to the antenna 414 or DC current drawn by the driver circuit 424. Transmit circuitry 406 further includes a driver circuit 424 configured to drive an RF signal as determined by an oscillator 423. The transmit circuitry 406 may be comprised of discrete devices or circuits, or alternately, may be comprised of an integrated assembly. An exemplary RF power output from transmit antenna 414 may be on the order of 2.5 Watts.

Transmit circuitry 406 may further include a controller 415 for selectively enabling the oscillator 423 during transmit phases (or duty cycles) for specific receivers, for adjusting the frequency or phase of the oscillator 423, and for adjusting the output power level for implementing a communication protocol for interacting with neighboring devices through their attached receivers. It is noted that the controller 415 may also be referred to herein as processor 415. Adjustment of oscillator phase and related circuitry in the transmission path may allow for reduction of out of band emissions, especially when transitioning from one frequency to another.

The transmit circuitry 406 may further include a load sensing circuit 416 for detecting the presence or absence of active receivers in the vicinity of the near-field generated by transmit antenna 414. By way of example, a load sensing circuit 416 monitors the current flowing to the driver circuit 424, that may be affected by the presence or absence of active receivers in the vicinity of the field generated by transmit antenna 414 as will be further described below. Detection of changes to the loading on the driver circuit 424 are monitored by controller 415 for use in determining whether to enable the oscillator 423 for transmitting energy and to communicate with an active receiver. As described more fully below, a current measured at the driver circuit 424 may be used to determine whether an invalid device is positioned within a wireless power transfer region of the transmitter 404.

The transmit antenna 414 may be implemented with a Litz wire or as an antenna strip with the thickness, width and metal type selected to keep resistive losses low. In a one implementation, the transmit antenna 414 may generally be configured for association with a larger structure such as a table, mat, lamp or other less portable configuration. Accordingly, the transmit antenna 414 generally may not need “turns” in order to be of a practical dimension. An exemplary implementation of a transmit antenna 414 may be “electrically small” (i.e., fraction of the wavelength) and tuned to resonate at lower usable frequencies by using capacitors to define the resonant frequency.

The transmitter 404 may gather and track information about the whereabouts and status of receiver devices that may be associated with the transmitter 404. Thus, the transmit circuitry 406 may include a presence detector 480, an enclosed detector 460, or a combination thereof, connected to the controller 415 (also referred to as a processor herein). The controller 415 may adjust an amount of power delivered by the driver circuit 424 in response to presence signals from the presence detector 480 and the enclosed detector 460. The transmitter 404 may receive power through a number of power sources, such as, for example, an AC-DC converter (not shown) to convert conventional AC power present in a building, a DC-DC converter (not shown) to convert a conventional DC power source to a voltage suitable for the transmitter 404, or directly from a conventional DC power source (not shown).

As a non-limiting example, the presence detector 480 may be a motion detector utilized to sense the initial presence of a device to be charged that is inserted into the coverage area of the transmitter 404. After detection, the transmitter 404 may be turned on and the RF power received by the device may be used to toggle a switch on the Rx device in a pre-determined manner, which in turn results in changes to the driving point impedance of the transmitter 404.

As another non-limiting example, the presence detector 480 may be a detector capable of detecting a human, for example, by infrared detection, motion detection, or other suitable means. In some exemplary embodiments, there may be regulations limiting the amount of power that a transmit antenna 414 may transmit at a specific frequency. In some cases, these regulations are meant to protect humans from electromagnetic radiation. However, there may be environments where a transmit antenna 414 is placed in areas not occupied by humans, or occupied infrequently by humans, such as, for example, garages, factory floors, shops, and the like. If these environments are free from humans, it may be permissible to increase the power output of the transmit antenna 414 above the normal power restrictions regulations. In other words, the controller 415 may adjust the power output of the transmit antenna 414 to a regulatory level or lower in response to human presence and adjust the power output of the transmit antenna 414 to a level above the regulatory level when a human is outside a regulatory distance from the electromagnetic field of the transmit antenna 414.

As a non-limiting example, the enclosed detector 460 (may also be referred to herein as an enclosed compartment detector or an enclosed space detector) may be a device such as a sense switch for determining when an enclosure is in a closed or open state. When a transmitter is in an enclosure that is in an enclosed state, a power level of the transmitter may be increased.

In exemplary embodiments, a method by which the transmitter 404 does not remain on indefinitely may be used. In this case, the transmitter 404 may be programmed to shut off after a user-determined amount of time. This feature prevents the transmitter 404, notably the driver circuit 424, from running long after the wireless devices in its perimeter are fully charged. This event may be due to the failure of the circuit to detect the signal sent from either the repeater or the receive antenna 218 that a device is fully charged. To prevent the transmitter 404 from automatically shutting down if another device is placed in its perimeter, the transmitter 404 automatic shut off feature may be activated only after a set period of lack of motion detected in its perimeter. The user may be able to determine the inactivity time interval, and change it as desired. As a non-limiting example, the time interval may be longer than that needed to fully charge a specific type of wireless device under the assumption of the device being initially fully discharged.

FIG. 5 is a functional block diagram of a receiver 508 that may be used in the wireless power transfer system of FIG. 1, in accordance with exemplary embodiments of the invention. The receiver 508 includes receive circuitry 510 that may include a receive antenna 518. Receiver 508 further couples to device 550 for providing received power thereto. It should be noted that receiver 508 is illustrated as being external to device 550 but may be integrated into device 550. Energy may be propagated wirelessly to receive antenna 518 and then coupled through the rest of the receive circuitry 510 to device 550. By way of example, the charging device may include devices such as mobile phones, portable music players, laptop computers, tablet computers, computer peripheral devices, communication devices (e.g., Bluetooth devices), digital cameras, hearing aids (and other medical devices), and the like.

Receive antenna 518 may be tuned to resonate at the same frequency, or within a specified range of frequencies, as transmit antenna 414 (FIG. 4). Receive antenna 518 may be similarly dimensioned with transmit antenna 414 or may be differently sized based upon the dimensions of the associated device 550. By way of example, device 550 may be a portable electronic device having diametric or length dimension smaller that the diameter of length of transmit antenna 414. In such an example, receive antenna 518 may be implemented as a multi-turn coil in order to reduce the capacitance value of a tuning capacitor (not shown) and increase the receive coil's impedance. By way of example, receive antenna 518 may be placed around the substantial circumference of device 550 in order to maximize the antenna diameter and reduce the number of loop turns (i.e., windings) of the receive antenna 518 and the inter-winding capacitance.

Receive circuitry 510 may provide an impedance match to the receive antenna 518. Receive circuitry 510 includes power conversion circuitry 506 for converting a received RF energy source into charging power for use by the device 550. Power conversion circuitry 506 includes an RF-to-DC converter 520 and may also in include a DC-to-DC converter 522. RF-to-DC converter 520 rectifies the RF energy signal received at receive antenna 518 into a non-alternating power with an output voltage represented by V_{rect}. The DC-to-DC converter 522 (or other power regulator) converts the rectified RF energy signal into an energy potential (e.g., voltage) that is compatible with device 550 with an output voltage and output current represented by Vₒᵤₜ and Iₒᵤₜ. Various RF-to-DC converters are contemplated, including partial and full rectifiers, regulators, bridges, doublers, as well as linear and switching converters.

Receive circuitry 510 may further include switching circuitry 512 for connecting receive antenna 518 to the power conversion circuitry 506 or alternatively for disconnecting the power conversion circuitry 506. Disconnecting receive antenna 518 from power conversion circuitry 506 not only suspends charging of device 550, but also changes the “load” as “seen” by the transmitter 404 (FIG. 2).

As disclosed above, transmitter 404 includes load sensing circuit 416 that may detect fluctuations in the bias current provided to transmitter driver circuit 424. Accordingly, transmitter 404 has a mechanism for determining when receivers are present in the transmitter's near-field.

When multiple receivers 508 are present in a transmitter's near-field, it may be desirable to time-multiplex the loading and unloading of one or more receivers to enable other receivers to more efficiently couple to the transmitter. A receiver 508 may also be cloaked in order to eliminate coupling to other nearby receivers or to reduce loading on nearby transmitters. This “unloading” of a receiver is also known herein as a “cloaking.” Furthermore, this switching between unloading and loading controlled by receiver 508 and detected by transmitter 404 may provide a communication mechanism from receiver 508 to transmitter 404 as is explained more fully below. Additionally, a protocol may be associated with the switching that enables the sending of a message from receiver 508 to transmitter 404. By way of example, a switching speed may be on the order of 100 psec.

In an exemplary embodiment, communication between the transmitter 404 and the receiver 508 refers to a device sensing and charging control mechanism, rather than conventional two-way communication (i.e., in band signaling using the coupling field). In other words, the transmitter 404 may use on/off keying of the transmitted signal to adjust whether energy is available in the near-field. The receiver may interpret these changes in energy as a message from the transmitter 404. From the receiver side, the receiver 508 may use tuning and de-tuning of the receive antenna 518 to adjust how much power is being accepted from the field. In some cases, the tuning and de-tuning may be accomplished via the switching circuitry 512. The transmitter 404 may detect this difference in power used from the field and interpret these changes as a message from the receiver 508. It is noted that other forms of modulation of the transmit power and the load behavior may be utilized.

Receive circuitry 510 may further include signaling detector and beacon circuitry 514 used to identify received energy fluctuations, that may correspond to informational signaling from the transmitter to the receiver. Furthermore, signaling and beacon circuitry 514 may also be used to detect the transmission of a reduced RF signal energy (i.e., a beacon signal) and to rectify the reduced RF signal energy into a nominal power for awakening either un-powered or power-depleted circuits within receive circuitry 510 in order to configure receive circuitry 510 for wireless charging.

Receive circuitry 510 further includes processor 516 for coordinating the processes of receiver 508 described herein including the control of switching circuitry 512 described herein. Cloaking of receiver 508 may also occur upon the occurrence of other events including detection of an external wired charging source (e.g., wall/USB power) providing charging power to device 550. Processor 516, in addition to controlling the cloaking of the receiver, may also monitor beacon circuitry 514 to determine a beacon state and extract messages sent from the transmitter 404. Processor 516 may also adjust the DC-to-DC converter 522 for improved performance.

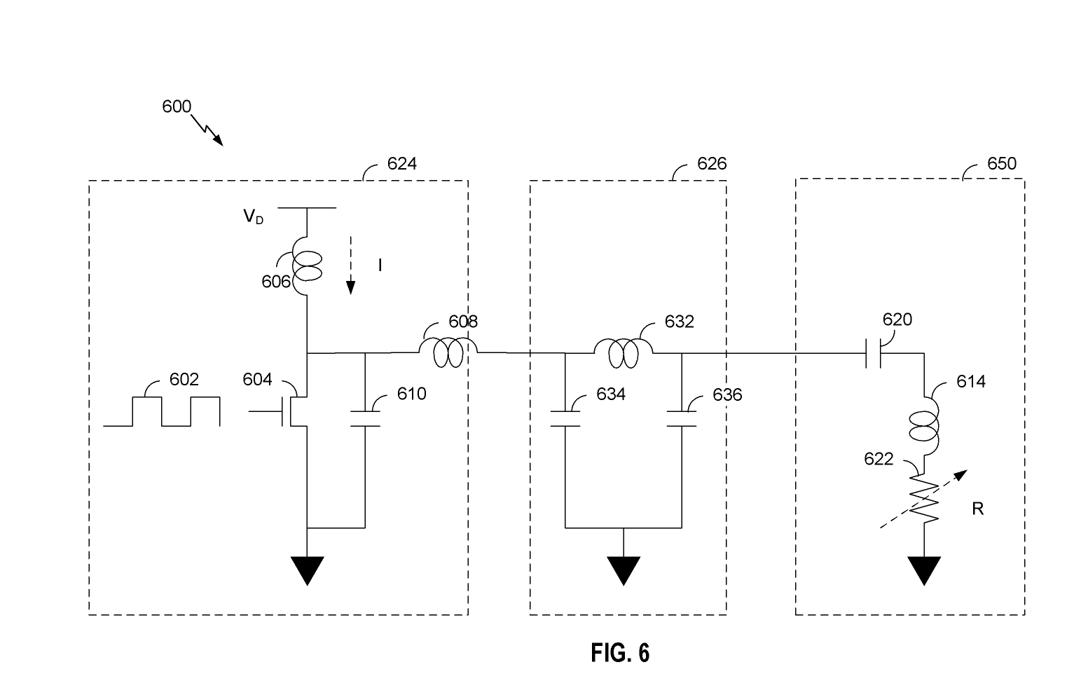

FIG. 6 is a schematic diagram of a portion of transmit circuitry 600 that may be used in the transmit circuitry 406 of FIG. 4. The transmit circuitry 600 may include a driver circuit 624 as described above in FIG. 4. The driver circuit 624 may be similar to the driver circuit 424 shown in FIG. 4. As described above, the driver circuit 624 may be a switching amplifier that may be configured to receive a square wave and output a sine wave to be provided to the transmit circuit 650. In some cases the driver circuit 624 may be referred to as an amplifier circuit. The driver circuit 624 is shown as a class E amplifier, however, any suitable driver circuit 624 may be used in accordance with embodiments of the invention. The driver circuit 624 may be driven by an input signal 602 from an oscillator 423 as shown in FIG. 4. The driver circuit 624 may also be provided with a drive voltage V_{D} that is configured to control the maximum power that may be delivered through a transmit circuit 650. To eliminate or reduce harmonics, the transmit circuitry 600 may include a filter circuit 626. The filter circuit 626 may be a three pole (capacitor 634, inductor 632, and capacitor 636) low pass filter circuit 626.

The signal output by the filter circuit 626 may be provided to a transmit circuit 650 comprising an antenna 614. The transmit circuit 650 may include a series resonant circuit having a capacitance 620 and inductance (e.g., that may be due to the inductance or capacitance of the antenna or to an additional capacitor component) that may resonate at a frequency of the filtered signal provided by the driver circuit 624. The load of the transmit circuit 650 may be represented by the variable resistor 622. The load may be a function of a wireless power receiver 508 that is positioned to receive power from the transmit circuit 650.

Operation of the wireless power transmitter 404 may result in undesired emissions in different parts of the system. For example, where a transmitter 404 and receiver 508 are loosely coupled (as compared to tightly coupled), the magnetic fields may not be well contained and may increase undesired emissions. A loosely coupled system may refer to a system as described herein with a coupling factor (k) indicative of an amount of flux penetrating a receiver coil 518 from a transmit coil 414 that is somewhere less than 0.5 (e.g., generally approximately or less than 0.2 or 0.1). A tightly coupled system may refer to a system with a coupling factor (k) greater than 0.5 (e.g., 0.8 or higher). As such, according to embodiments described herein, multiple different sources and paths for undesired emissions may be suppressed to meet emission limits. For example, harmonics from the receiver 508 may couple back into the transmitter 414. These emissions, and emissions from the driver circuit 624 and/or other components, may further be reflected back into a DC line feeding the transmit circuitry. As such, undesired emissions may be produced in a DC cable by operation of the wireless power transmitter.

In accordance with aspects of certain embodiments, the DC cable may include a filter circuit. In one aspect, the DC cable may be a Universal Serial Bus (USB) cable, although other cables may be used in accordance with the principles described herein. The filter circuit may be configured to electrically isolate emissions. In one aspect, if the DC cable is configured to be connected to and to provide power to a wireless power transmitter, the DC cable may be configured to electrically isolate emissions from the driver circuit 624 and the transmit circuit 650 to the power source. For example, a filter circuit in the DC cable in accordance with embodiments may be configured to reject or attenuate emissions at a particular frequency or within a particular frequency range such as a range of frequencies including the operating frequency used for wireless power transmission. In an embodiment, the filter circuit may be configured to reject harmonic emissions below 30 MHz for conductive emissions. In an embodiment, the filter circuit may be configured to reduce/attenuate harmonic emissions below 30 MHz by substantially 15 dB. Other frequencies are also possible and the specific frequencies listed here are exemplary only. In one embodiment, the filter circuit may be implemented as a common mode choke circuit. In another embodiment, the filter circuit may include a common mode choke circuit and may include a further filter circuit (such as a differential filter circuit—e.g., a differential LC filter circuit).

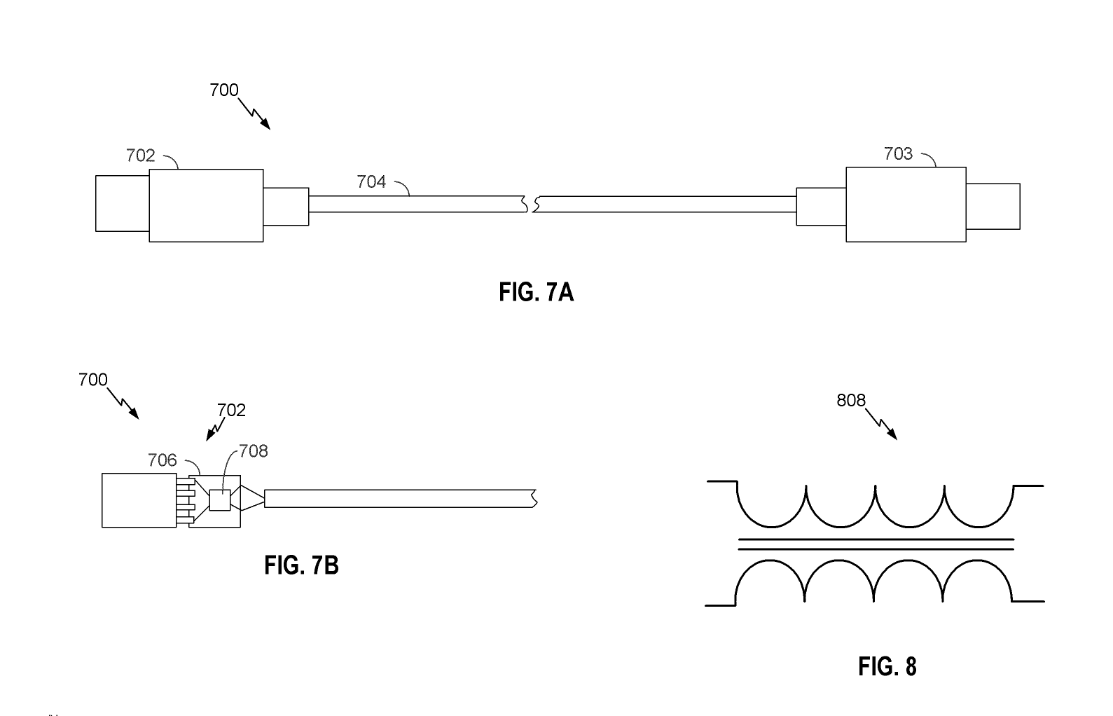

FIG. 7A is a diagram of a cable 700, in accordance with an exemplary embodiment. The cable 700 may be configured to connect to any one of a number of different electronic devices and provide power and/or data. For example, the cable 700 may be configured to selectively couple and provide DC power to a wireless power transmitter 404. The cable 700 may be configured as a USB cable. The cable includes a cable portion 704, a first connector portion 703 and a second connector portion 702. In one aspect, having to implement a filter circuit as described above in a power adapter or a ferrite bead on the power cable may be undesirable due to the need for either a custom power adaptor and/or reduced aesthetics that might result from a ferrite bead positioned on a cable. As such, in accordance with an embodiment, a filter circuit is hidden within the second connector portion 702 (e.g., in a USB cable on the USB A side). The A side of a USB cable may be configured for connection to the host device or the device supplying power to a device connected to the opposite side of the USB cable. Thus, where the cable 700 is a DC cable providing DC power to the wireless power transmitter circuitry, for example the driver circuit 624 and/or the transmit circuit 650 shown in FIG. 6, the filter circuit may be located in the second connector portion 702 located at a second end of the cable 700 opposite a first end, connected to or configured for connection to the wireless power transmitter circuitry. In this way, especially where the filter comprises a common mode choke, the filter may be located as far as possible from the primary source of electromagnetic emissions the filter circuit is intended to isolate from the DC power source. Moreover, the above-mentioned physical location of the filter circuit with respect to the wireless power transmitter circuitry may additionally apply where the DC cable is not a USB cable.

FIG. 7B is diagram of a portion of the cable 700 of FIG. 7B, in accordance with an embodiment. As shown in FIG. 7B, a filter circuit 708 is hidden within the second connector portion 702. The second connector portion may have a PCB 706. The filter circuit 708 is positioned and/or integrated with the PCB 706. The filter circuit 708 may be configured to be similar to and/or smaller in size than the second connector portion 702. In this way, when the filter circuit 708 is integrated with the second connector portion 702, the second connector portion 702 remains the same (e.g., form factor of the connector/entire cable is unaffected by the addition of the filter circuit 708). In this way the aesthetics of the cable is preserved while providing filtering capabilities.

FIG. 8 is a schematic diagram of a filter circuit 808 in accordance with an embodiment. In FIG. 8, the filter circuit 808 is configured as a common mode choke. As described above, the filter circuit 808 may further include a differential filter circuit in addition to the common mode choke circuit shown. However, other filter circuits may be used in accordance with the embodiments described herein. While portions of the disclosure with regards to the power cable have been described in relation to a wireless power transfer system, it is noted that the power cable and filter circuit may be used in any one of a number of systems where further filtering may be desirable. As such, the cable 700 in accordance with embodiments is not limited to being used with a wireless power transfer system.

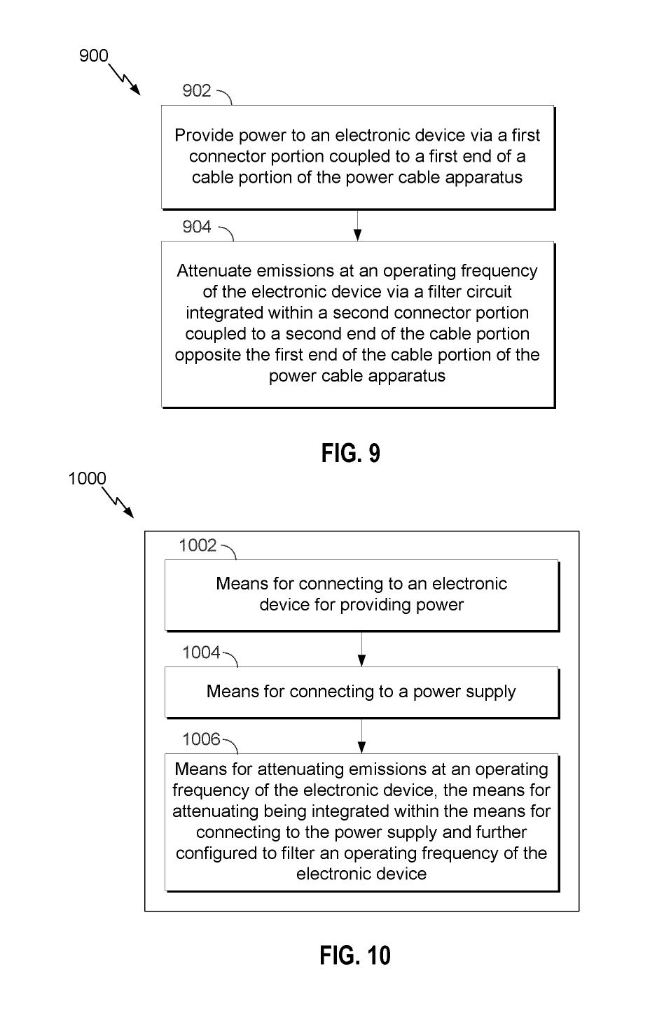

FIG. 9 is a flow chart of an exemplary method 900 of filtering within a power cable apparatus, in accordance with an exemplary embodiment. Block 902 may include providing power to an electronic device via a first connector portion coupled to a first end of a cable portion of the power cable apparatus. The method may continue with block 904, which may include attenuating emissions at an operating frequency of the electronic device via a filter circuit integrated within a second connector portion coupled to a second end of the cable portion opposite the first end of the cable portion of the power cable apparatus. In some implementations, the filter circuit may be configured to be smaller than the second connector portion. In some other implementations, the filter circuit may comprise a common mode choke circuit, such as that previously described in connection with FIG. 8. In another implementation, the filter circuit may comprise the common mode choke circuit and a differential filter circuit. In some implementations, the power cable apparatus may comprise a USB power cable and the second connector portion may comprise an A side connector of the USB power cable. In some implementations, emissions of a wireless power transmitter into a power supply coupled to the second connector may be reduced utilizing the filter circuit.

FIG. 10 is a functional block diagram of a power cable apparatus 1000, in accordance with an exemplary embodiment of the invention. Those skilled in the art will appreciate that the apparatus may have more components than illustrated in FIG. 10. The apparatus 1000 includes only those components useful for describing some prominent features of implementations within the scope of the claims. In one implementation, the apparatus 1000 is configured to perform the method 900 shown above in FIG. 9. The apparatus 1000 may comprise the power cable apparatus 700 shown in FIG. 7A, for example, which may be shown in more detail in one or more of FIGS. 6, 7B and 8.

The apparatus 1000 comprises means 1002 for connecting to an electronic device for providing power. In some implementations, the means 1002 can be configured to perform one or more of the functions described above with respect to block 902 of FIG. 9. As previously described in connection with FIG. 7A, the means 1002 may comprise the first connector portion 703 shown in FIG. 7A, for example.

The apparatus 1000 may further include means 1004 for connecting to a power supply. In some implementations, the means 1004 can be configured to perform one or more of the functions described above with respect to block 902 of FIG. 9. The means 1004 may comprise the second connector portion 702 shown in FIG. 7, for example.

The apparatus 1000 may further include means 1006 for attenuating emissions at an operating frequency of the electronic device, the means for attenuating being integrated within the means for connecting to the power supply. In some implementations, the means 1006 may be configured to be smaller than the means for connecting to the power supply. In some implementations, the means 1006 can be configured to perform one or more of the functions described above with respect to block 904 of FIG. 9. The means 1006 may comprise the filter circuit 708 shown in FIG. 7B, for example.

The various operations of methods described above may be performed by any suitable means capable of performing the operations, such as various hardware and/or software component(s), circuits, and/or module(s). Generally, any operations illustrated in the Figures may be performed by corresponding functional means capable of performing the operations. For example, a means for selectively allowing current in response to a control voltage may comprise a first transistor. In addition, means for limiting an amount of the control voltage comprising means for selectively providing an open circuit may comprise a second transistor.

Information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. The described functionality may be implemented in varying ways for each particular application, but such implementation decisions should not be interpreted as causing a departure from the scope of the embodiments of the invention.

The various illustrative blocks, modules, and circuits described in connection with the embodiments disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm and functions described in connection with the embodiments disclosed herein may be embodied directly in hardware, in a software module executed by a processor, or in a combination of the two. If implemented in software, the functions may be stored on or transmitted over as one or more instructions or code on a tangible, non-transitory computer-readable medium. A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD ROM, or any other form of storage medium known in the art. A storage medium is coupled to the processor such that the processor can read information from, and write information to, the storage medium. In the alternative, the storage medium may be integral to the processor. Disk and disc, as used herein, includes compact disc (CD), laser disc, optical disc, digital versatile disc (DVD), floppy disk and blu ray disc where disks usually reproduce data magnetically, while discs reproduce data optically with lasers. Combinations of the above should also be included within the scope of computer readable media. The processor and the storage medium may reside in an ASIC. The ASIC may reside in a user terminal. In the alternative, the processor and the storage medium may reside as discrete components in a user terminal.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

Various modifications of the above described embodiments will be readily apparent, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

What is claimed is:

1. A power cable apparatus, the apparatus comprising:
a cable portion;
a first connector portion coupled to a first end of the cable portion and configured to selectively couple to an electronic device;
a second connector portion coupled to a second end of the cable portion opposite the first end; and
a filter circuit integrated within the second connector portion, the filter circuit configured to attenuate emissions at an operating frequency of the electronic device.

2. The apparatus of claim 1, wherein the filter circuit comprises a common mode choke circuit.

3. The apparatus of claim 1, wherein the filter circuit is integrated within the second connector portion such that a form factor of the second connector portion is maintained the same when integrated with the filter circuit.

4. The apparatus of claim 1, wherein the filter circuit comprises a differential filter circuit.

5. The apparatus of claim 1, wherein the power cable apparatus comprises a Universal Serial Bus (USB) power cable and the second connector portion comprises a USB A side connector.

6. The apparatus of claim 1, wherein the first connector is configured to selectively couple to a wireless power transmitter, and the filter circuit is configured to reduce emissions from the wireless power transmitter into a power supply coupled to the second connector.

7. The apparatus of claim 1, comprising a DC power cable apparatus.

8. A method of filtering within a power cable apparatus, the method comprising:
providing power to an electronic device via a first connector portion coupled to a first end of a cable portion of the power cable apparatus; and
attenuating emissions at an operating frequency of the electronic device via a filter circuit integrated within a second connector portion coupled to a second end of the cable portion opposite the first end of the cable portion of the power cable apparatus.

9. The method of claim 8, wherein the filter circuit comprises a common mode choke circuit.

10. The method of claim 9, wherein the filter circuit is integrated within the second connector portion such that a form factor of the second connector portion is maintained the same when integrated with the common mode choke circuit.

11. The method of claim 8, wherein the filter circuit comprises a differential filter circuit.

12. The method of claim 8, wherein the power cable apparatus comprises a Universal Serial Bus (USB) power cable and the second connector portion comprises a USB A side connector.

13. The method of claim 8, further comprising:
selectively coupling the first connector to a wireless power transmitter; and
reducing emissions from the wireless power transmitter into a power supply coupled to the second connector utilizing the filter circuit.

14. The method of claim 8, wherein the power cable apparatus comprises a DC power cable apparatus.

15. A DC power cable apparatus, the apparatus comprising:
means for connecting to an electronic device for providing power;
means for connecting to a power supply; and
means for attenuating emissions at an operating frequency of the electronic device, the means for attenuating being integrated within the means for connecting to the power supply.

16. The apparatus of claim 15, wherein the means for attenuating comprises a common mode choke circuit.

17. The apparatus of claim 16, wherein the means for attenuating is integrated within the means for connecting to the power supply such that a form factor of the means for connecting to the power supply is maintained the same when integrated with the common mode choke circuit.

18. The apparatus of claim 15, wherein the means for attenuating comprises a differential filter circuit.

19. The apparatus of claim 15, wherein the apparatus comprises a Universal Serial Bus (USB) power cable, and the means for connecting to a power supply comprises a USB A side connector.

20. The apparatus of claim 15, the means for connecting to the electronic device being configured to selectively couple to a wireless power transmitter, and the means for attenuating being configured to reduce emissions from the wireless power transmitter into the power supply coupled to the means for connecting to the power supply.
